(19) United States
(12) Patent Application Publication
(10) Pub. No.: US 2025/0251045 A1
(43) Pub. Date: Aug. 7, 2025

(54) TRIPLE PREVENTION GATE VALVE WITH HEATING FUNCTION

(71) Applicant: Science Probe Co., Ltd., Hwaseong-si (KR)

(72) Inventors: Jung-Ryul HAN, Seoul (KR); Do-Ryeong PARK, Hwaseong-si (KR)

(21) Appl. No.: 18/437,186

(22) Filed: Feb. 8, 2024

(30) Foreign Application Priority Data
Feb. 2, 2024 (KR) 10-2024-0016810

(51) Int. Cl. F16K 1/46; F16K 3/02; F16K 27/04; F16K 27/12; F16K 49/00

(52) U.S. Cl. CPC F16K 1/465; F16K 3/0236; F16K 27/044; F16K 27/12; F16K 49/002; F16K 2200/101

(57) ABSTRACT

The triple prevention gate valve according to the present invention comprises a rectangular housing (10) with a slide space (11) formed inside and a circular main passage (12) formed on both sides with an outer diameter smaller than the width of the slide space (11) towards the bottom side; a disk valve assembly (20) installed to be movable within the slide space (11) and selectively opening and closing the main passage (12); an actuator (30) for moving the disk valve assembly (20) to open and close the main passage (12); a first ring guide (40) installed on one side of the housing (10) and communicating with the main passage (12); a second ring guide (50) provided on the opposite side of the first ring guide (40) and communicating with the main passage (12); a protection ring (60) provided inside the second ring guide (50), capable of reciprocating sliding through the main passage (12), blocking the slide space (11) or opening it to allow the ingress of the disk valve assembly (20) depending on its slide state; and a heating unit (80) provided along at least one outer surface of either the first ring guide (40) or the second ring guide (50) for heating.

### CROSS-REFERENCE TO RELATED APPLICATION

This application claims priority from and the benefit of Korean Patent Application No. 10-2024-0016810, filed on Feb. 2, 2024, which is hereby incorporated by reference for all purposes as if fully set forth herein.

### BACKGROUND

### Field

The present invention relates to a gate valve that automatically shields between a chamber and a passage in a semiconductor manufacturing process. More specifically, it pertains to a triple prevention gate valve that can prevent damage caused by powder generated during the process.

### Discussion of the Background

Generally, in the etching, deposition, and sputtering processes of LCD substrates or semiconductor wafers, a gate valve is installed between the chamber and the passage to maintain or release the vacuum state inside the chamber. This gate valve is installed between the chamber and the passage, consisting of a housing with a flow path formed, a disc valve that selectively opens and closes the flow path while being transported in the slide space within the housing, and an actuator that moves the disc valve within the slide space to open and close the flow path. By this structure, the actuator moves the disc valve to selectively open and close the flow path, thereby maintaining or releasing the vacuum state inside the chamber.

However, as the semiconductor process progresses, there have been cases where process gases or generated powder enter the gate valve, leading to corrosion or deposition of powder inside the gate valve components. Eventually, this could result in an inability to perfectly seal the flow path or cause damage. As a result, it became necessary to maintain or replace the gate valve periodically or irregularly, and in severe cases, to replace the gate valve entirely.

### SUMMARY

The invention was created to solve the aforementioned problems, aiming to provide a triple prevention gate valve that can prevent particles such as gas or generated powder from penetrating into the slide space during the process. This prevents damage to the internal components over time, enabling a perfect seal and preventing damage.

The invention relates to a triple prevention gate valve, which includes a rectangular housing (10) with an internal slide space (11) and a circular main passage (12) on both sides, smaller in outer diameter than the width of the slide space (11) towards the bottom side; a disk valve assembly (20) installed within the slide space (11) capable of selectively opening and closing the main passage (12); an actuator (30) for moving the disk valve assembly (20) to open and close the main passage (12); a first ring guide (40) installed on one side of the housing (10) and communicating with the main passage (12); a second ring guide (50) provided on the opposite side of the first ring guide (40) and communicating with the main passage (12); a protection ring (60) provided inside the second ring guide (50) for reciprocating sliding through the main passage (12), blocking the slide space (11) or opening it to allow the ingress of the disk valve assembly (20) depending on its slide state; and a heating unit (80) provided along at least one outer surface of either the first ring guide (40) or the second ring guide (50) for heating.

Additionally, the housing (10), the first ring guide (40), or the second ring guide (50) may include a thermos stop part for measuring temperature and stopping the heating of the heating unit (80) when the measured temperature exceeds a preset temperature.

Furthermore, the heating unit may comprise a circular metal tube, a heating wire within the tube, and magnesia powder filling the tube for insulating the heating wire from the tube.

The housing may be made from aluminum material to allow the heat transferred from the heating unit to be released.

The housing may also include a heat dissipation unit (90) on its exterior to prevent the heat released from the heating unit from transferring upwards.

The heat dissipation unit (90) may further include a heat exchanger to facilitate cooling.

The protection ring (60) may be made of stainless steel material.

The disk valve assembly (20) may include a guide plate (21) with multiple guide pins (21a) protruding from its surface; multiple roller units (22) installed at the edges of the guide plate (21) supported by the upper and lower inner surfaces of the slide space (11) for rolling motion; a sealing disk (23) located at the top side of the guide plate (21) for selectively opening and closing the main passage (12); a rear disk (24) supported by the guide pins (21a) for vertical movement at the bottom side of the guide plate (21); a leaf spring assembly (25) connecting the insides of the sealing disk (23) and the rear disk (24) at both ends; a stopper plate (26) supported on the guide plate (21) in a protruding state at the front side, to which one end of the leaf spring assembly (25) is connected; and a ball drive unit (27) that causes the sealing disk (23) and the rear disk (24) to move apart when the guide plate (21) is pushed towards the stopper plate (26).

The leaf spring assembly (25) may provide a traction force due to elasticity in the direction that brings the sealing disk (23) and the rear disk (24) closer together when the gap between them widens due to the operation of the ball drive unit (27).

The disk valve assembly (20) may further include a shield bar (70) installed on the front side, sealing against the inner surfaces of the slide space (11) during transportation.

The ball drive unit (27) may include several first balls (27a) protruding on one side of the guide plate (21); multiple first ball guide grooves (27b) formed on the sealing disk (23) for the first balls (27a) to fit into, becoming progressively deeper from one side to the other; several second balls (27c) protruding on the opposite side of the guide plate (21); and multiple second ball guide grooves (27d) formed on the rear disk (24) for the second balls (27c) to fit into, becoming progressively deeper from one side to the other.

The roller unit (22) may include a central shaft (221); a wheel part (223) that rotates around the shaft (221); a bearing part (222) provided between the shaft (221) and the wheel part (223) to reduce friction during rotation; a cover part (224) that encases the bearing part to prevent it from being exposed to the outside; and a retention part (226) fixed to the shaft to prevent the cover part from detaching.

According to the invention, when the disc valve assembly is positioned in the slide space, a protection ring is coupled to penetrate the main flow path and communicate with the first ring guide. This configuration prevents process gas or generated powder from infiltrating the slide space, thus preventing damage to internal components over time and ensuring a perfect seal at all times.

Moreover, the heat provided through the heating section is transferred to the protection ring to prevent the adhesion of particles as much as possible, thereby delaying maintenance due to particle adhesion.

Additionally, the roller part, which facilitates the movement of components for opening and closing the flow path, is equipped with a shield structure to prevent particles from adhering to the internal bearings, further delaying maintenance caused by particle adhesion.

Even as the disc valve assembly is transported through the slide space, a shield bar installed in the front can closely adhere to the inner surfaces of the slide space in all directions. This prevents process gas and powder from infiltrating the slide space again, thereby fundamentally preventing corrosion or damage to the disc valve assembly, offering significant protective effects and benefits.

### BRIEF DESCRIPTION OF THE DRAWINGS

FIG. 1 is a perspective view of the triple prevention gate valve according to the present invention.

FIG. 2 is a partial sectional view of the triple prevention gate valve of FIG. 1.

FIG. 3 is a partially cutaway drawing for explaining the internal configuration of the triple prevention gate valve of FIG. 1.

FIG. 4 is a perspective view showing the disk valve assembly and the first and second links according to an embodiment.

FIG. 5 is a perspective view of the disk valve assembly of FIG. 3.

FIG. 6 is a rear perspective view of the disk valve assembly of FIG. 4.

FIGS. 7 and 8 are schematic diagrams for explaining the operation in which the sealing disk and the rear disk of the disk valve assembly of FIG. 4 are separated.

FIG. 9 is a drawing for explaining the configuration of the first and second ring guides of FIG. 1.

FIG. 10 is a sectional view showing the state of the protection ring slid according to an embodiment.

FIG. 11 is a schematic diagram showing the appearance of the disk valve assembly transported towards the main flow side, with the protection ring slid in the direction of the first ring guide according to an embodiment.

FIG. 12 is a schematic diagram showing the appearance of the disk valve assembly further transported so that the gap between the sealing disk and the rear disk widens, and the sealing disk seals the main flow.

FIG. 13 is a drawing showing the appearance of the roller according to an embodiment.

### DETAILED DESCRIPTION

Referencing the attached drawings for a detailed explanation of embodiments of the invention, terms used to indicate directions in this description are based on the orientation as shown in the figures, unless otherwise defined or mentioned. The same reference numerals in different embodiments refer to the same elements. Moreover, the thickness or dimensions of each component shown in the drawings may be exaggerated for clarity of explanation and do not necessarily represent the actual proportions or relationships between components.

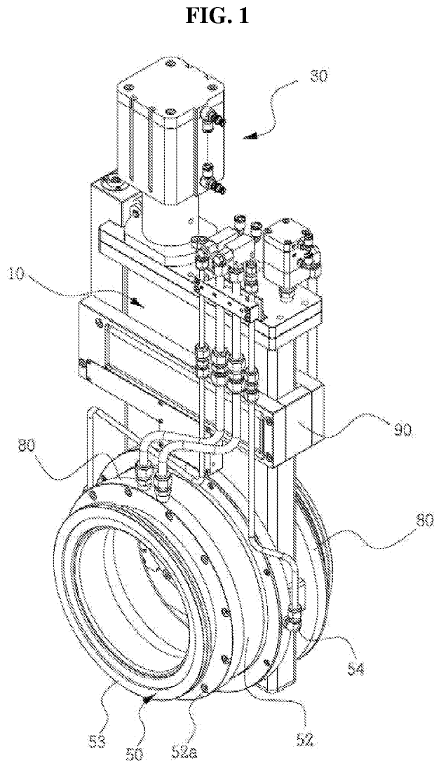

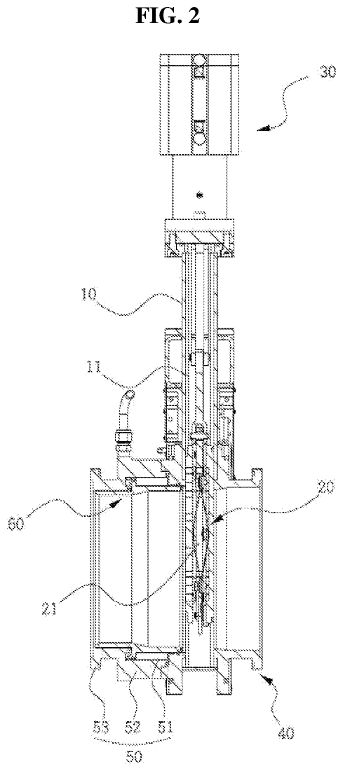

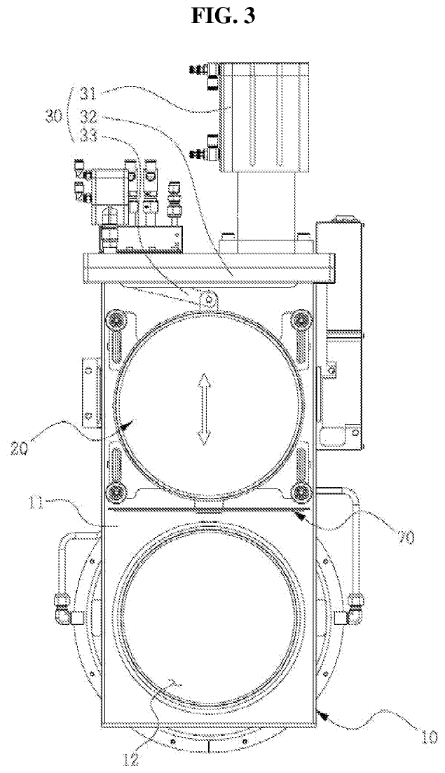

Refer to FIGS. 1 through 3 for an explanation of a triple prevention gate valve according to an embodiment of the invention. FIG. 1 is a perspective view of the triple prevention gate valve according to the invention, FIG. 2 is a partial cross-sectional view of the triple prevention gate valve of FIG. 1, and FIG. 3 is a partially cutaway drawing to explain the internal structure of the triple prevention gate valve of FIG. 1.

As shown, the triple prevention gate valve according to the invention comprises a rectangular housing (10) with a slide space (11) formed inside and a circular main passage (12) of a smaller outer diameter than the width of the slide space (11) formed on both sides towards the lower side; a disc valve assembly (20) installed to be movable within the slide space (11) and selectively open or close the main passage (12); an actuator (30) installed on the housing (10) to move the disc valve assembly (20) for opening or closing the main passage (12); a first ring guide (40) installed on one side of the housing (10) and communicating with the main passage (12); a second ring guide (50) installed on the other side of the housing (10) and communicating with the main passage (12) opposite the first ring guide (40); and a protection ring (60) fitted into the second ring guide (50) and designed to move through the main passage (12) and couple with the first ring guide (40) when the disc valve assembly (20) is positioned in the slide space (11); and a shield bar (70) installed on the front side of the disc valve assembly (20) to seal tightly against the inner surface of the slide space (11) in all directions during movement.

The actuator (30) selectively opens or closes the main passage (12) by moving the disc valve assembly (20) within the slide space (11), comprising an actuator body (31) installed on the upper side of the housing (10), a first link (32) connected to the actuator body (31) to rotate within the slide space (11), and a second link (33) connecting the first link (32) with a guide plate (21). This structure enables the actuator body (31) to reciprocate the disc valve assembly (20) within the slide space (11) by folding or unfolding the first and second links (32) (33).

The shield bar (70) is installed on the front side of the disc valve assembly (20), sealing tightly against the four directional inner surfaces surrounding the slide space (11) during movement. To enhance sealing within the slide space (11), the shield bar (70) further includes a sealing member (71) at its edge, which seals against the inner surfaces on all sides surrounding the slide space (11).

A heating unit (80) is provided along the outer circumference of at least one of the first ring guide (40) and the second ring guide (50) to heat them. The heating unit (80) includes an unshown circular metal tube, a heating wire inside the metal tube, and magnesia powder filling the metal tube to insulate the heating wire from the metal tube.

Furthermore, the housing (10), the first ring guide (40), or the second ring guide (50) may include an unshown thermostat part to measure temperature and stop heating from the heating unit (80) if the measured temperature exceeds a preset temperature.

The housing (10) could be made from aluminum to allow heat transferred from the heating unit (80) to dissipate and may include a heat dissipation part (90) on its exterior to prevent heat from the heating unit (80) from transferring upwards. By positioning components for various controls or those sensitive to heat above and blocking heat transferred upwards through the heat dissipation effect of the heat dissipation part (90) or the housing (10), durability degradation due to heat can be minimized.

Additionally, the heat dissipation part (90) may further include a heat exchanger to facilitate heat dissipation. For example, using a water-cooled or air-cooled heat exchanger is possible, as is implementing a system that cools the upper part of the housing (10) and transfers heat to the lower part using thermoelectric elements or similar technology.

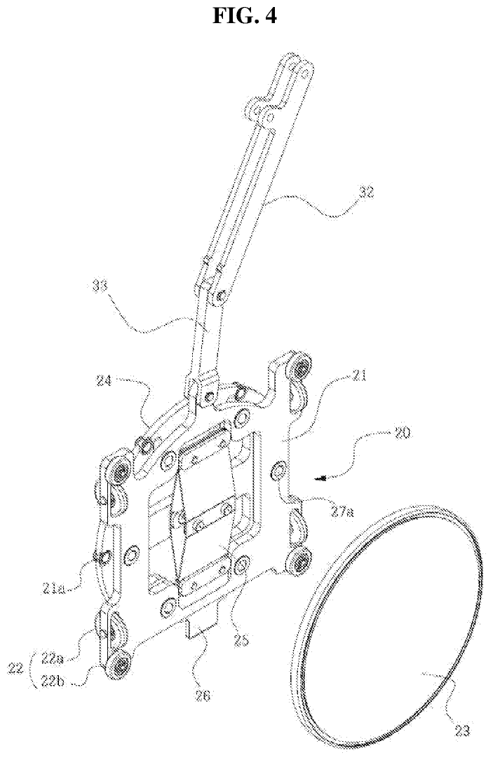

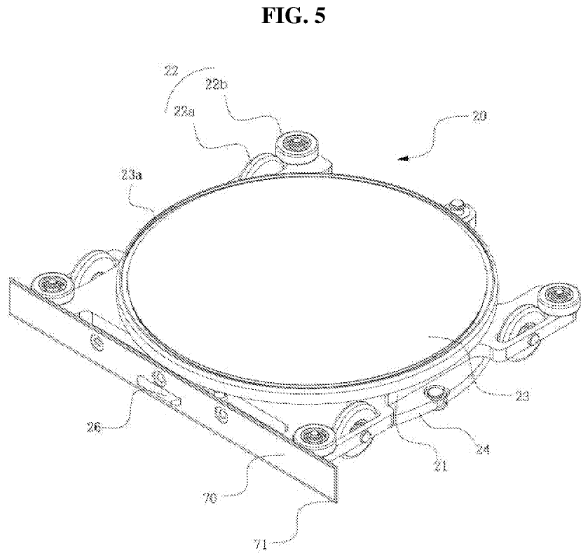

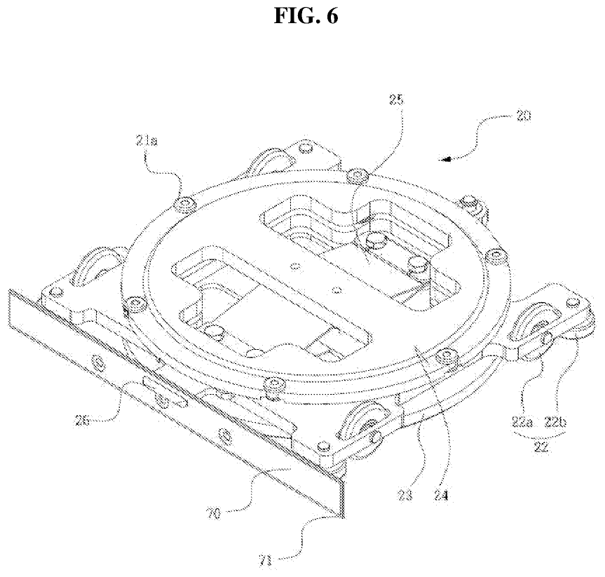

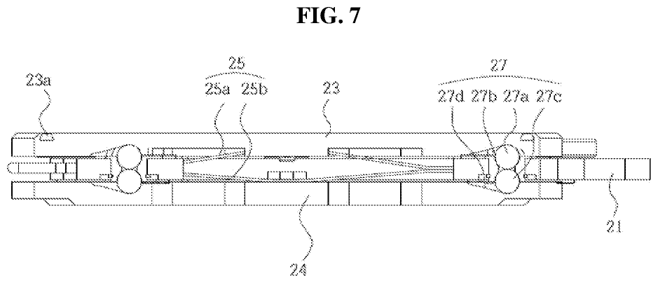

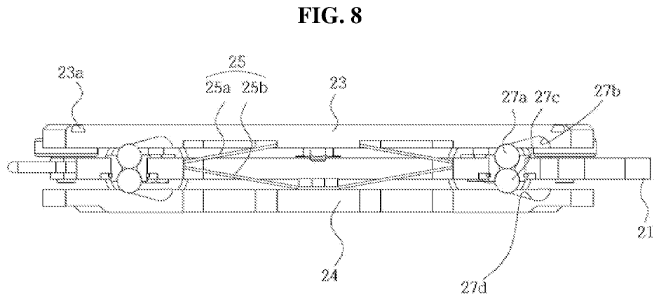

Referencing FIGS. 4 to 8, the disk valve assembly is described in detail. FIG. 4 is a perspective view showing the disk valve assembly and the first and second links according to an embodiment. FIG. 5 is a perspective view of the disk valve assembly as seen in FIG. 3. FIG. 6 is a rear perspective view of the disk valve assembly shown in FIG. 4. FIGS. 7 and 8 are schematic diagrams explaining the operation of the sealing disk and rear disk of the disk valve assembly shown in FIG. 4 moving apart.

The disk valve assembly (20) includes a guide plate (21) that is movable within the slide space (11) and features a multitude of protruding guide pins (21a), a plurality of rollers (22) installed at the edges of the guide plate (21) supporting and enabling rolling motion along the upper and lower inner surfaces of the slide space (11), a sealing disk (23) located at the top side of the guide plate (21) for selectively sealing the main passage (12), a rear disk (24) supported by the guide pins (21a) in a manner allowing vertical movement on the lower side of the guide plate (21), a leaf spring assembly (25) connecting the insides of the sealing disk (23) and the rear disk (24) at both ends, a stopper plate (26) supported on the guide plate (21) in a protruding manner at the front side and to which one end of the leaf spring assembly (25) is connected, and a ball drive unit (27) which causes the sealing disk (23) and the rear disk (24) to move apart when the guide plate (21) is pushed towards the stopper plate (26).

The roller unit (22) comprises four transport rollers (22a) installed at the corners of the guide plate (21) for rolling motion along the upper and lower inner surfaces of the slide space (11), and four side rollers (22b) installed at the corners for rolling motion along the left and right inner surfaces of the slide space (11), as shown in FIGS. 4 to 6. This arrangement allows the guide plate (21) to move back and forth accurately within the slide space (11).

The sealing disk (23) is positioned opposite the rear disk (24) by the leaf spring assembly (25) and selectively seals the main passage (12). The edge surface of the sealing disk (23) features an O-ring (23a) to maintain a complete seal when coupled with the main passage (12). The O-ring (23a) is made from Viton material to withstand high temperatures and chemical environments.

The rear disk (24) can move a predetermined distance vertically, supported by the guide pins (21a).

The leaf spring assembly (25) connects the ends of a first leaf spring (25a) supporting the sealing disk (23) and a second leaf spring (25b) supporting the rear disk (24), forming a closed loop in a diamond shape overall.

The stopper plate (26) has a partially protruding form on the front side of the guide plate (21) and supports relative movement. One end of the leaf spring assembly (25) is connected to this stopper plate (26).

The ball drive unit (27), as shown in FIGS. 7 and 8, includes several first balls (27a) protruding on one side of the guide plate (21), multiple first ball guide grooves (27b) formed on the sealing disk (23) for the first balls (27a) to fit into, several second balls (27c) protruding on the opposite side of the guide plate (21), and multiple second ball guide grooves (27d) formed on the rear disk (24) for the second balls (27c) to fit into, with the grooves deepening from one side to the other.

The first and second balls (27a) and (27c) protrude from the surface of the guide plate (21) towards opposite sides. Initially, as shown in FIG. 7, the leaf spring assembly (25) maintains the sealing disk (23) and rear disk (24) in opposing positions. When the guide plate (21) moves towards the stopper plate (26), as shown in FIG. 8, the first and second balls (27a) and (27c) move to the shallower side of their respective guide grooves (27b) and (27d), causing the gap between the sealing disk (23) and the rear disk (24) to widen through this operating mechanism.

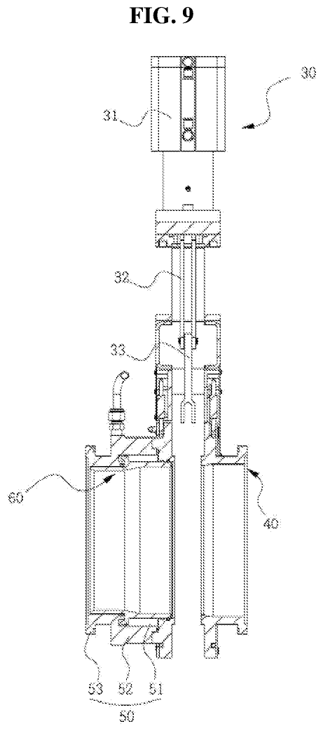

Referencing FIG. 9, the first and second ring guiders are described. FIG. 9 is a diagram for explaining the configuration of the first and second ring guiders in FIG. 1.

The first ring guider (40) is installed on one side of the housing (10) and communicates with the main passage (12), connecting to one of the chambers or passages for entry and exit during the process, through which process gas is introduced.

The second ring guider (50) is installed on the opposite side of the housing (10) where the process gas introduced from the first ring guider (40) is exhausted. This ring guider (50) includes a guider body (52) with a cylinder groove (51) formed on its inner surface that has a stepped distance, a sub-guider body (53) extending from the guider body (52) with an inner diameter smaller than that of the cylinder groove (51), and a pair of air connectors (54) installed on the guider body (52) to supply or exhaust air to the cylinder groove (51). The guider body (52) is designed with multiple flange holes (52a) for coupling to a chamber or passage.

The protection ring (60) consists of a ring body (61) that fits into the guider body (52) and sub-guider body (53), and a piston ring (62) formed on the ring body (61) that closely adheres to the inner surface of the cylinder groove (51). To prevent powder generated by the process gas entering through the first ring guider (40) from adhering to the inner surface of the protection ring (60), the flow rate must be increased. For this purpose, the inner diameter at the exit side of the first ring body (61) near the first ring guider (40) is made smaller than the inner diameter at the entry side.

Due to the structure of the second ring guider (50) and the protection ring (60), the protection ring (60) is positioned in the guider body (52) and sub-guider body (53) of the second ring guider (50). When air is supplied through the pair of air connectors (54) while the disk valve assembly (20) is positioned inside the slide space (11), the protection ring (60) moves through the main passage (12) to communicate with the second ring guider (50).

The protection ring (60) can be made of stainless steel. While lightweight aluminum could be considered for the metal constituting the protection ring (60) due to its weight advantage, stainless steel is preferred to maximize the effect of preventing particles from adhering due to heat transfer.

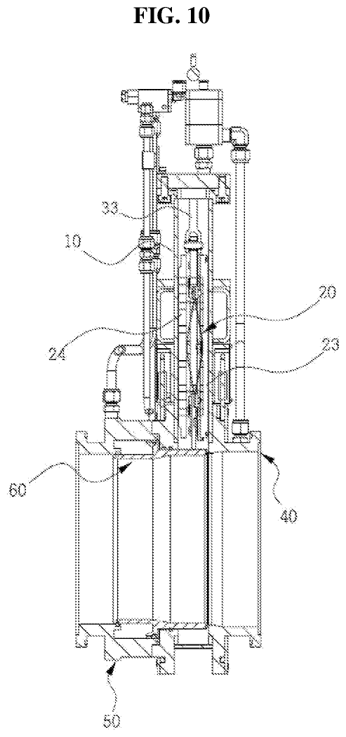

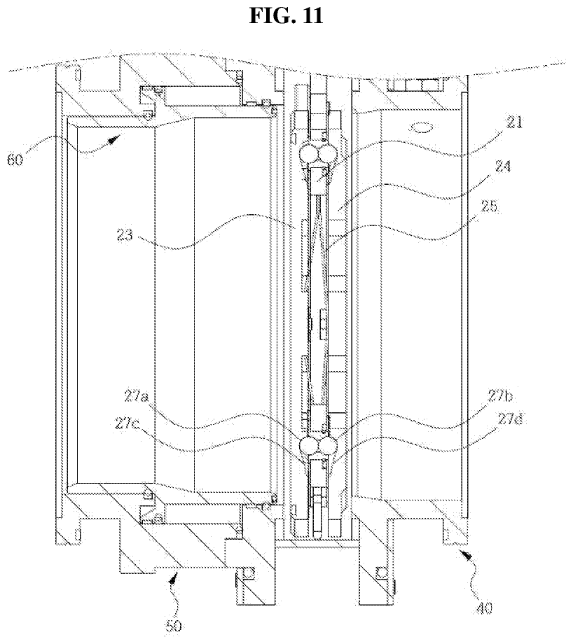

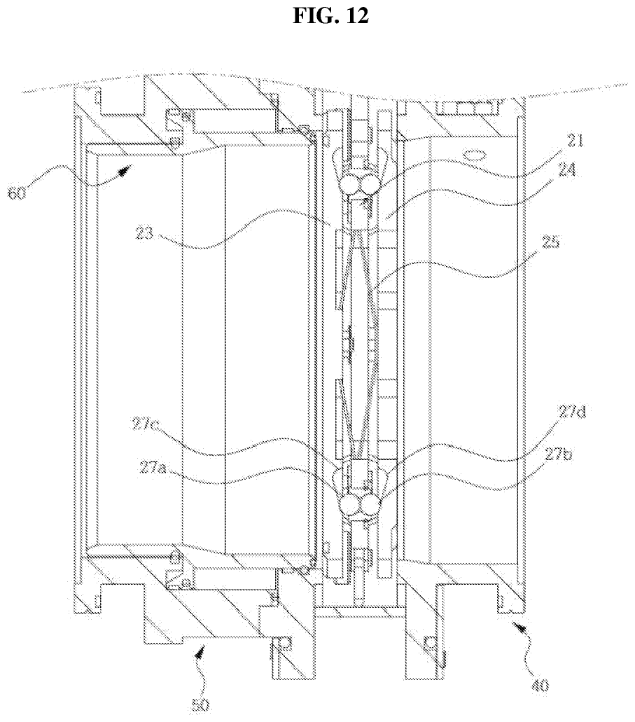

Referencing FIGS. 10 to 12, the operation and appearance of the protection ring and the disk valve assembly (20) are explained. FIG. 10 is a sectional view explaining the state where the protection ring penetrates the main passage (12) and communicates with the second ring guide (50) when the disk valve assembly is located in the slide space. FIG. 11 is a schematic showing the protection ring slid towards the direction of the first ring guide (40), with the disk valve assembly transported towards the side of the main passage (12), according to an embodiment. FIG. 12 is a schematic depicting the disk valve assembly further transported, widening the gap between the sealing disk and the rear disk, with the sealing disk sealing the main passage (12).

As described with reference to FIG. 10, when the disk valve assembly (20) is positioned in the slide space (11), the protection ring (60) maintains close contact, penetrating the main passage (12) and communicating with the second ring guide (50). In this state, the chambers and passages communicate through the first and second ring guides (40, 50), effectively isolating the slide space (11) from the main passage (12). This prevents process gases or particles generated during the process from entering the slide space (11), protecting the disk valve assembly from corrosion or damage.

When air is supplied to or exhausted from the cylinder groove (51) through the air connector (54; see FIG. 1), causing expansion or contraction, the protection ring (60) moves towards the second ring guide (50). As air is supplied or exhausted, the space within the cylinder groove (51) expands or contracts, causing the second ring guide (50) to move towards the first ring guide (40).

Initially, as shown in FIG. 11, after moving the protection ring (60) to the left side, i.e., towards the second ring guide (50), the actuator (30) operates to extend the first and second links (32, 33), transporting the disk valve assembly (20) towards the main passage (12). A shield bar (70), as shown in FIG. 3, is installed on the front side of the disk valve assembly (20), sealing against the inner surfaces of the slide space (11) during transportation, thus preventing process gases or particles from flowing towards the disk valve assembly (20).

As the actuator's first and second links (32, 33) fully push the disk valve assembly (20), as shown in FIG. 12, the guide plate (21) is pushed, and through the operation of the ball drive unit (27), the sealing disk (23) seals the main passage (12) in a closed state.

The leaf spring assembly (25) provides a traction force due to elasticity in the direction that brings the sealing disk (23) and the rear disk (24) closer together when the gap between them widens due to the operation of the ball drive unit (27). Thus, when the first and second links (32, 33) are retracted, pulling the disk valve assembly (20) back, the guide plate (21) is drawn back, causing the ball drive unit (27) to disengage, narrowing the gap between the sealing disk (23) and the rear disk (24), and the sealing disk (23) no longer seals the main passage (12).

Accordingly, with this invention, when the disk valve assembly (20) is positioned in the slide space (11), the protection ring (60) penetrating and communicating with the first ring guide (40) through the main passage (12) prevents process gases or generated powder from infiltrating the slide space, ensuring that the internal components are not damaged over time and always allowing for a perfect seal.

Additionally, even as the disk valve assembly (20) is transported within the slide space (11), the front-installed shield bar (70) can seal against the inner surfaces of the slide space (11), preventing process gases or powder from infiltrating the slide space (11) again, fundamentally preventing corrosion or damage to the disk valve assembly (20).

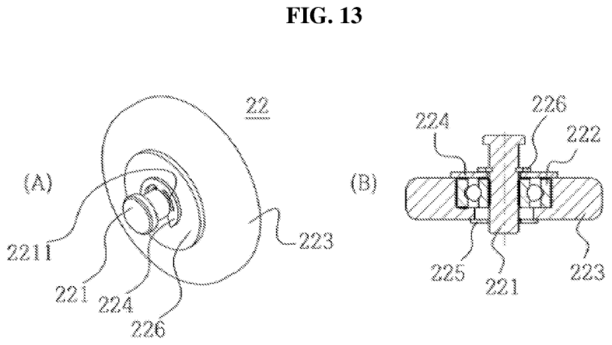

Referring to FIG. 13, the roller (22) according to an embodiment is explained. FIG. 13 is a drawing showing the appearance of a roller according to an embodiment.

The roller unit (22) may include a shaft (221) serving as the rotation center; a wheel part (223) rotating around the shaft (221); a bearing part (222) positioned between the shaft (221) and the wheel part (223) to reduce friction during rotation; a cover part (224) that prevents the bearing part from being exposed to the exterior; and a retention part (226) fixed to the shaft to prevent the cover part from detaching.

Through such a structure, it's possible to prevent particles from adhering to the roller bearing assembly, ensuring smoother and more reliable operation of the roller.

In contexts like semiconductor manufacturing equipment, it's necessary to perform overhauls for the maintenance of the entire equipment, typically on a set schedule. Halting semiconductor manufacturing equipment for maintenance can incur substantial economic losses due to downtime. Therefore, the maintenance operations or replacement cycles for consumables within semiconductor manufacturing equipment are often determined by the components or tasks with the shortest cycle times. If equipment is already down for maintenance, it's usually advantageous to perform as many maintenance tasks as possible, unless doing so would significantly extend the downtime beyond what is necessary for the overhaul.

In this sense, technologies that prevent the adhesion of particles to small components are crucial. They can extend the overall maintenance cycle of the equipment, resulting in significant economic benefits by reducing downtime and extending the intervals between necessary maintenance and consumable replacements.

A person skilled in the art of this field of the invention would understand that the invention can be implemented in other specific forms without altering its technical spirit or essential features. Therefore, the embodiments described above should be considered in all respects as illustrative and not restrictive. The scope of the invention is defined by the claims that follow, rather than the detailed description above, and all changes or modifications derived from the meaning and range of the claims and their equivalent concepts should be interpreted as being included within the scope of the invention.

What is claimed is:

1. A triple prevention gate valve comprising:
a rectangular housing (10) having a slide space (11) formed therein and a circular main passage (12) formed on both sides thereof, the main passage (12) having an outer diameter smaller than the width of the slide space (11) towards the bottom side;
a disk valve assembly (20) installed to be movable within the slide space (11) and selectively opening and closing the main passage (12);
an actuator (30) for moving the disk valve assembly (20) to open and close the main passage (12);
a first ring guide (40) installed on one side of the housing (10) and communicating with the main passage (12);
a second ring guide (50) provided on the opposite side of the first ring guide (40) and communicating with the main passage (12);
a protection ring (60) provided inside the second ring guide (50), capable of reciprocating sliding through the main passage (12), blocking the slide space (11) or opening it to allow the ingress of the disk valve assembly (20) depending on its slide state; and
a heating unit (80) provided along at least one outer surface of either the first ring guide (40) or the second ring guide (50) for heating.

2. The triple prevention gate valve of claim 1, further comprising a thermos stop part provided on at least one of the housing (10), the first ring guide (40), and the second ring guide (50), for measuring temperature and stopping the heating of the heating unit (80) when the measured temperature exceeds a preset temperature.

3. The triple prevention gate valve of claim 1, wherein the heating unit comprises a circular metal tube, a heating wire provided inside the metal tube, and magnesia powder filled in the metal tube to insulate the heating wire from the metal tube.

4. The triple prevention gate valve of claim 1, wherein the housing is made of aluminum material to allow heat transferred from the heating unit to be discharged.

5. The triple prevention gate valve of claim 1, further comprising a heat dissipation unit (90) on the exterior of the housing to prevent heat discharged from the heating unit from being transferred upwards.

6. The triple prevention gate valve of claim 5, wherein the heat dissipation unit (90) further includes a heat exchanger to facilitate heat dissipation.

7. The triple prevention gate valve of claim 1, wherein the protection ring (60) is made of stainless steel.

8. The triple prevention gate valve of claim 1, wherein the disk valve assembly (20) comprises:
a guide plate (21) with several protruding guide pins (21a) that moves within the slide space (11);
several roller units (22) installed at the edges of the guide plate (21) supported by the upper and lower inner surfaces of the slide space (11) for rolling movement;
a sealing disk (23) located on the top side of the guide plate (21) for selectively opening and closing the main passage (12);
a rear disk (24) supported by the guide pins (21a) on the lower side of the guide plate (21) for vertical movement;
a leaf spring assembly (25) connecting the insides of the sealing disk (23) and rear disk (24) at both ends;
a stopper plate (26) protruded from the front side of the guide plate (21) and movably supported on the guide plate (21) with one end of the leaf spring assembly (25) connected; and
a ball drive unit (27) that causes the sealing disk (23) and rear disk (24) to move apart when the guide plate (21) is pushed towards the stopper plate (26).

9. The triple prevention gate valve of claim 8, wherein the leaf spring assembly (25) provides an elastic traction force to bring the sealing disk (23) and rear disk (24) closer together when the gap between them widens due to the action of the ball drive unit (27).

10. The triple prevention gate valve of claim 8, further comprising a shield bar (70) installed on the front side of the disk valve assembly (20) that seals against the upper, lower, left, and right inner surfaces of the slide space (11) during transportation.

11. The triple prevention gate valve of claim 8, wherein the ball drive unit (27) includes:
multiple first balls (27a) protruding from one side of the guide plate (21); 2 multiple first ball guide grooves (27b) formed on the sealing disk (23) for accommodating the first balls (27a), deepening from one side to the other;
multiple second balls (27c) protruding from the opposite side of the guide plate (21); and
multiple second ball guide grooves (27d) formed on the rear disk (24) for accommodating the second balls (27c), deepening from one side to the other.

12. The triple prevention gate valve of claim 8, wherein the roller unit (22) includes:
a shaft (221) as the center of rotation;
a wheel part (223) that rotates around the shaft (221);
a bearing part (222) provided between the shaft (221) and the wheel part (223) to reduce friction during rotation;
a cover part (224) that covers the bearing part to prevent it from being exposed to the outside; and
a retention part (226) fixed to the shaft to prevent the cover part from detaching.
